(19) United States
(12) Patent Application Publication
(10) Pub. No.: US 2025/0201157 A1
(43) Pub. Date: Jun. 19, 2025

(54) Display Device

(71) Applicant: LG Display Co., Ltd., Seoul (KR)

(72) Inventors: Sumin Lee, Seoul (KR); ByungHyun Lee, Paju-si (KR); Daeyoung Seo, Seoul (KR); MinSeok Kim, Seoul (KR); TaeYong Kim, Anyang-si (KR)

(21) Appl. No.: 18/904,655

(22) Filed: Oct. 2, 2024

(30) Foreign Application Priority Data
Dec. 15, 2023 (KR) 10-2023-0182651

(51) Int. Cl. G09G 3/00; G09G 3/32; H01L 25/075; H01L 25/16; H01L 33/62

(52) U.S. Cl. CPC G09G 3/006; G09G 3/32; H01L 25/0753; H01L 25/167; H10H 20/857; G09G 2300/026; G09G 2330/10

(57) ABSTRACT

A display device comprises a substrate having a plurality of sub pixels and one or more repair sub pixels disposed thereon, a high potential power line disposed in the plurality of sub pixels and the repair sub pixels, a driving transistor disposed in each of the plurality of sub pixels and each of the repair sub pixels, a sensing layer disposed on the high potential power line in each of the plurality of sub pixels and each of the repair sub pixels, an insulation layer disposed on the sensing layer in the plurality of sub pixels and the repair sub pixels, a light emitting element disposed between the sensing layer and the insulation layer in each of the plurality of sub pixels, and an additional light emitting element disposed on the insulation layer in the repair sub pixels.

### CROSS-REFERENCE TO RELATED APPLICATION

This application claims the priority of Republic of Korea Patent Application No. 10-2023-0182651 filed on Dec. 15, 2023, in the Korean Intellectual Property Office, which is hereby incorporated by reference in its entirety.

### FIELD

The present disclosure relates to a display device, and particularly, a display device using a light emitting diode (LED).

### DESCRIPTION OF THE RELATED ART

Display devices used for a computer monitor or a television (TV), a mobile phone and the like include an organic light emitting display (OLED) device and the like emitting light on its own, and a liquid crystal display (LCD) device and the like requiring a separate light source.

Display devices have been widely applied to a variety of areas ranging from a computer monitor and a TV to a personal mobile device, and research has been conducted into display devices that have a wide display surface area and has a reduced volume and weight.

Additionally, in recent years, a display device including a light emitting diode (LED) has drawn attention as a next-generation display device. The LED is made of an inorganic material rather than an organic material, thereby securing excellent reliability and a lifespan longer than that of a liquid crystal display device or an organic light emitting display device. Further, the LED can ensure a fast-lighting speed, excellent light emission efficiency, and excellent impact resistance and high reliability, and display an image of high luminance.

### SUMMARY

An object to be achieved by the present disclosure is to provide a display device that may readily sense a defective sub pixel to which a light emitting element is not transferred.

Another object to be achieved by the present disclosure is to provide a display device that may readily sense a defective sub pixel to which a light emitting element is not transferred by using a sensing transistor.

Still another object to be achieved by the present disclosure is to provide a display device that may sense a non-transfer failure by short-circuiting a sensing layer and a first connection electrode in a defective sub pixel to which a light emitting element is not transferred.

Still another object to be achieved by the present disclosure is to provide a display device that may repair a defective sub pixel to which a light emitting element is not transferred.

Still another object to be achieved by the present disclosure is to provide a display device that may perform repairs by transferring an additional light emitting element to a defective sub pixel.

Still another object to be achieved by the present disclosure is to provide a display device that may repair a defective sub pixel and ensure improvement in yields.

Objects of the present disclosure are not limited to the above-mentioned objects, and other objects, which are not mentioned above, can be clearly understood by those skilled in the art from the following descriptions.

In one embodiment, a display device comprises: a substrate; a plurality of sub pixels and a repair sub pixel on the substrate; a high potential power line in the plurality of sub pixels and the repair sub pixel; a plurality of driving transistors, each driving transistor in a corresponding one of the plurality of sub pixels or the repair sub pixel; a plurality of light emitting elements on the high potential power line, each light emitting element in a corresponding one of the plurality of sub pixels; an insulation layer on the plurality of light emitting elements such that plurality of light emitting elements are between at least a portion of the insulation layer and the high potential power line; and an additional light emitting element in the repair sub pixel, the additional light emitting element on the insulation layer such that insulation layer is between the additional light emitting element and the high potential power line.

In one embodiment, a display device comprises: a substrate; a sub pixel and a repair sub pixel on the substrate; a first driving transistor in the sub pixel and a second driving transistor in the repair sub pixel; a high potential power line in the sub pixel and the repair sub pixel; a first insulating layer on the high potential power line in the sub pixel and the repair sub pixel; a second insulating layer on the first insulating layer in the sub pixel and the repair sub pixel; a first light emitting element in the sub pixel, the first light emitting element electrically connected to the first driving transistor; a second light emitting element in the repair sub pixel, the second light emitting element connected to the second driving transistor; a first connection electrode in the sub pixel that is electrically connected to the first light emitting element and is disposed in a first contact hole that extends through the second insulating layer without extending through the first insulating layer in the sub pixel; and a first connection electrode in the repair sub pixel that is electrically connected to the second light emitting element and is disposed in a first contact hole that extends through the second insulating layer and the first insulating layer in the repair sub pixel.

Other detailed matters of the exemplary embodiments are included in the detailed description and the drawings.

According to the present disclosure, the light emitting element may readily sense a defective sub pixel.

According to the present disclosure, a defective sub pixel to which the light emitting element is not transferred may be readily detected with a sensing transistor rather than a lighting test.

According to the present disclosure, in a sub pixel where a non-transfer failure occurs, the sensing layer and a first connection electrode may be short-circuited to sense the non-transfer failure.

According to the present disclosure, the light emitting element may repair a defective sub pixel to which the light emitting element is not transferred.

According to the present disclosure, the additional light emitting element may be transferred to a defective sub pixel to repair the defective sub pixel.

According to the present disclosure, yields may improve by repairing a defective sub pixel.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to one embodiment;

FIG. 2A is a partial cross-sectional view of the display device according to one embodiment;

FIG. 2B is a perspective view of a tiled display device according to one embodiment;

FIG. 3 is an enlarged schematic plan view of an active area of the display device according to one embodiment;

FIG. 4 is a circuit diagram of a sub pixel and a repair sub pixel of the display device according to one embodiment;

FIG. 5 is an enlarged plan view of area A of FIG. 3 according to one embodiment;

FIGS. 6 and 7 are cross-sectional views of a sub pixel of the display device according to one embodiment;

FIGS. 8 and 9 are cross-sectional views of a repair sub pixel of the display device according to one embodiment;

FIG. 10 is a circuit diagram of a repair sub pixel of the display device of one embodiment prior to a repair process; and

FIG. 11 is a cross-sectional view of a repair sub pixel of the display device according to one embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

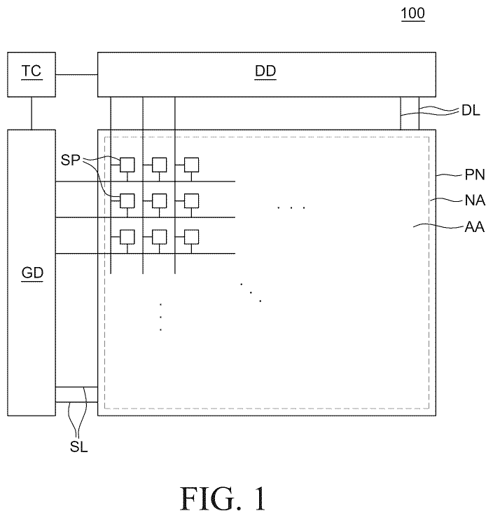

FIG. 1 is a schematic diagram of a display device of one embodiment. In FIG. 1, a display panel PN, a gate driver GD, a data driver DD, and a timing controller TC are illustrated among a variety of components of a display device 100, for convenience of description.

Referring to FIG. 1, the display device 100 comprises the display panel PN comprising a plurality of sub pixels SP, the gate driver GD, and the data driver DD providing various types of signals to the display panel PN, and a timing controller TC controlling the gate driver GD and the data driver DD.

The gate driver GD provides a plurality of scan signals to a plurality of scan lines SL according to a plurality of gate control signals provided by the timing controller TC. In FIG. 1, one gate driver GD is disposed at one side of the display panel PN in such a way that the gate driver GD is spaced from the display panel PN, but the number and the positions of the gate drivers GD are not limited thereto.

The data driver DD provides a data voltage to a plurality of data lines DL according to a plurality of data control signals and image data provided by the timing controller TC. The data driver DD may convert image data to a data voltage by using a reference gamma voltage, and provide the converted data voltage to the plurality of data lines DL.

The timing controller TC aligns image data input from the outside and provides the aligned image data to the data driver DD. The timing controller TC may generate a gate control signal and a data control signal by using a synchronization signal, e.g., a dot clock signal, a data enable signal, and a horizontal/vertical synchronization signal, input from the outside. Additionally, the timing controller TC provides the generated gate control signal and the generated data control signal respectively to the gate driver GD and the data driver DD to control the gate driver GD and the data driver DD.

The display panel PN, as a component for displaying an image to the user, comprises a plurality of sub pixels SP. In the display panel PN, the plurality of scan lines SL and the plurality of data lines DL may cross each other, and at a point where the scan line SL and the data line DL cross each other, the plurality of sub pixels SP may be formed.

In the display panel PN, an active area AA and a non-active area NA may be defined.

The active area AA is an area where an image is displayed, in the display device 100. In the active area AA, a plurality of sub pixels SP constituting a plurality of pixels PX and a pixel circuit for driving the plurality of sub pixels SP may be disposed. The plurality of sub pixels SP are a minimum unit constituting the active area AA, and n numbers of sub pixels SP may form one pixel PX. In each of the plurality of sub pixels SP, a thin film transistor for driving a plurality of light emitting elements 120 and the like may be disposed. The plurality of light emitting elements 120 may be defined in a different manner, depending on the sort of display panel PN. For example, in the case where the display panel PN is an inorganic light emitting display panel PN, the light emitting element 120 may be a light-emitting diode (LED) or a micro light-emitting diode (LED).

In the active area AA, a plurality of signal lines delivering various types of signals to the plurality of sub pixels SP are disposed. For example, the plurality of signal lines may comprise a plurality of data lines DL providing a data voltage to each of the plurality of sub pixels SP, a plurality of scan lines SL providing a scan signal to each of the plurality of sub pixels SP, and the like. The plurality of scan lines SL may connect to the plurality of sub pixels SP while extending from the active area AA in one direction, and the plurality of data lines DL may connect to the plurality of sub pixels SP while extending from the active area AA in a direction different from the one direction. In addition, a low potential power line VSS, a high potential power line VDD and the like may be further disposed in the active area AA, and not limited thereto.

The non-active area NA, as an area where an image is not displayed, may be defined as an area extending from the active area AA. In the non-active area NA, link lines and pad electrodes for delivering a signal to sub pixels SP in the active area AA, or driving ICs such as a gate driver IC, a data driver IC and the like, and the like may be disposed.

Additionally, the non-active area NA may be placed on the back surface, i.e., a surface without a sub pixel SP, of the display panel PN or may be omitted, and not limited to the one illustrated in the drawing.

Further, a driving part such as a gate driver GD, a data driver DD and a timing controller TC may connect to the display panel PN in various ways. For example, the gate driver GD may be mounted in the non-active area NA based on a gate in panel (GIP) method, or may be mounted between the plurality of sub pixels SP in the active area AA based on a gate in active area (GIA) method.

For example, the data driver DD and the timing controller TC may be formed on a separate flexible film and a printed circuit board 110, and electrically connected to the display panel PN, the data driver DD and the timing controller TC in such a way that the flexible film and the printed circuit board 110 are bonded to the pad electrode formed in the non-active area NA of the display panel PN.

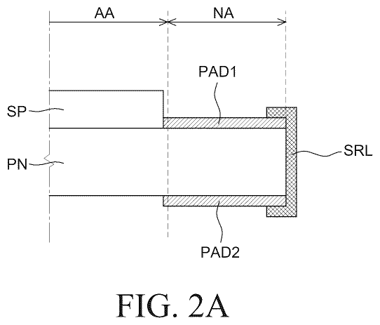

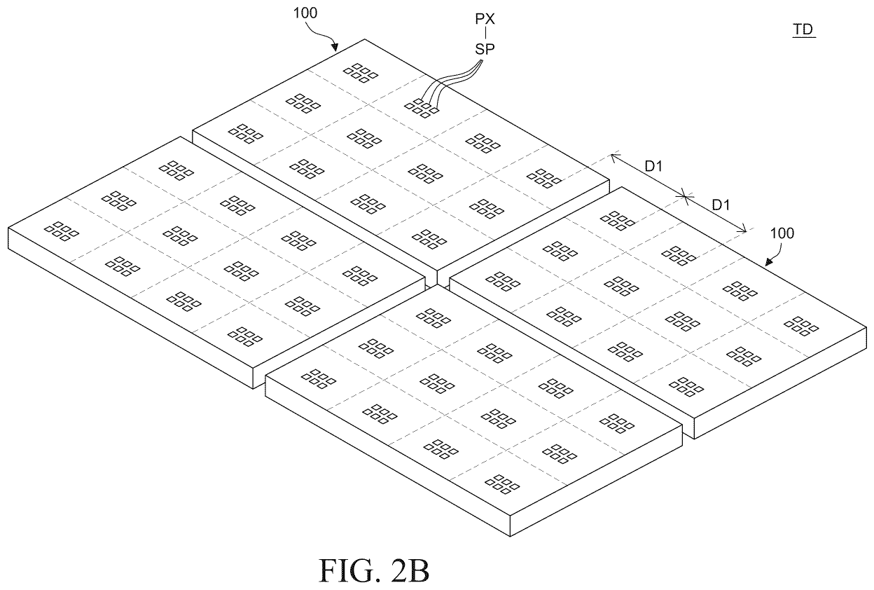

In another example, in the case where the gate driver GD is mounted in the active area AA based on a GIA method, and by forming side lines SRL connecting signal lines on the front surface of the display panel PN with pad electrodes on the back surface of the display panel PN, the flexible film and the printed circuit board 110 are bonded to the back surface of the display panel PN, the non-active area NA may be minimized as much as possible on the front surface of the display panel PN. Accordingly, the gate driver GD, the data driver DD and the timing controller TC connect with the display panel PN based on the above-described method, so that a zero bezel substantially without a bezel may be embodied, and detailed description in relation to this is provided with reference to FIGS. 2A and 2B.

FIG. 2A is a partial cross-sectional view of the display device according to one embodiment. FIG. 2B is a perspective view of a tiled display device according to one embodiment.

In the non-active area NA of the display panel PN, a plurality of pad electrodes for delivering various types of signals to the plurality of sub pixels SP are disposed. For example, a first pad electrode PAD1 delivering signals to the plurality of sub pixels SP is disposed in the non-active area NA on the front surface of the display panel PN, and a second pad electrode PAD2 which is electrically connected to a driving component, such as a flexible film and a printed circuit board 110 is disposed in the non-active area NA on the back surface of the display panel PN.

At this time, though not illustrated in the drawings, various types of signal lines, e.g., scan lines SL or data lines DL and the like, connecting to the plurality of sub pixels SP may extend to the non-active area NA from the active area AA to be electrically connect to the first pad electrode PAD1.

Additionally, the side line SRL is disposed along the lateral surface of the display panel PN. The side line SRL may be electrically connected to the first pad electrode PAD1 on the front surface of the display panel PN and the second pad electrode PAD2 on the back surface of the display panel PN. Accordingly, signals from the driving component on the back surface of the display panel PN may be delivered to the plurality of sub pixels SP through the second pad electrode PAD2, the side line SRL and the first pad electrode PAD1. Thus, the driving component is disposed on the back surface of the display panel PN, and a signal delivery path between the front surface of the display panel PN and the back surface thereof is formed, to minimize the surface area of the non-active area NA on the front surface of the display panel PN.

Referring to FIG. 2B, a plurality of display devices 100 are connected to embody a tiled display device TD having a large screen. At this time, in the case where a tiled display device TD is embodied with a display device 100 the bezel of which is minimized as illustrated in FIG. 2A, a seam area where an image is not displayed, between a display device 100 and a display device 100, is minimized, enhancing display quality.

For example, a plurality of sub pixels SP may form one pixel PX, and an interval D1 between an outermost pixel PX of one display device 100 and an outermost pixel PX of another display device 100 adjacent to the one display device 100 may be the same as the interval D1 between pixels PX in one display device 100. Accordingly, the seam area may be minimized as a constant interval of the pixels PX is implemented between the display device 100 and the display device 100.

However, FIGS. 2A and 2B show an example, and the display device 100 of one embodiment may be an ordinary display device with a bezel, and not limited thereto.

Hereinafter, the display panel PN of the display device 100 of one embodiment is specifically described.

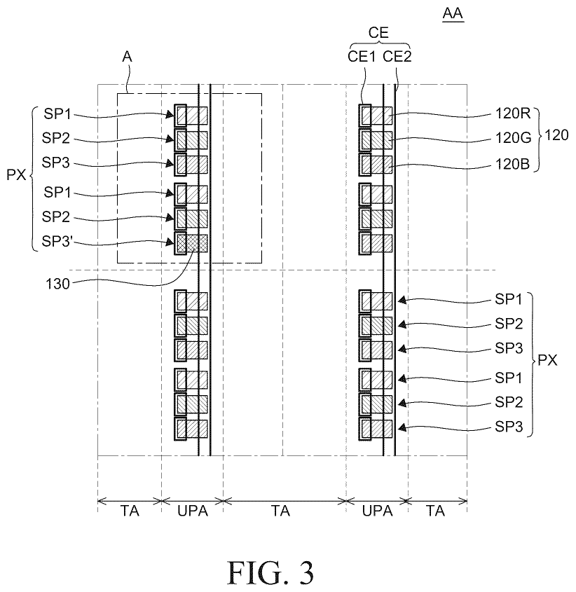

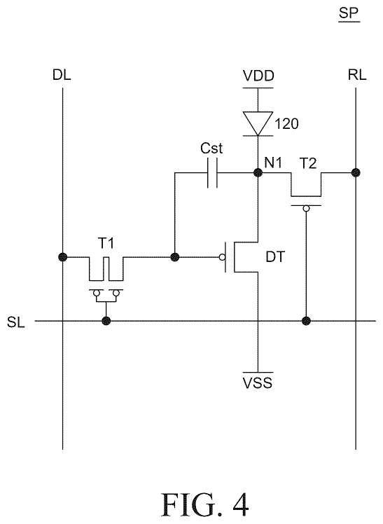

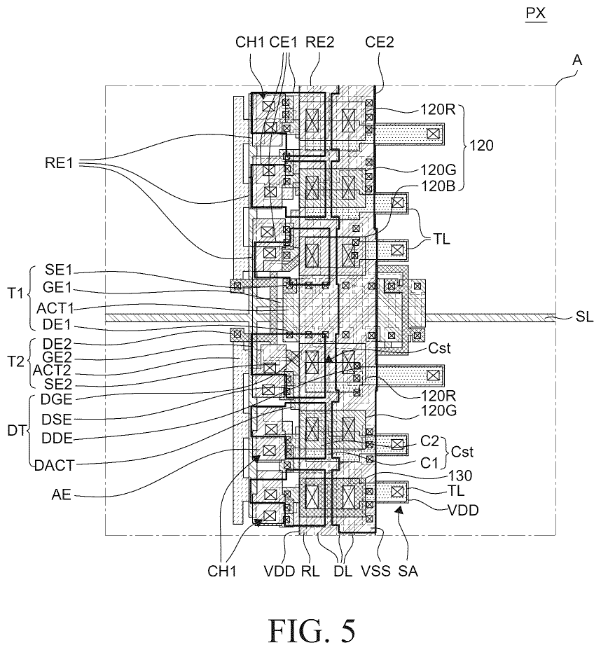

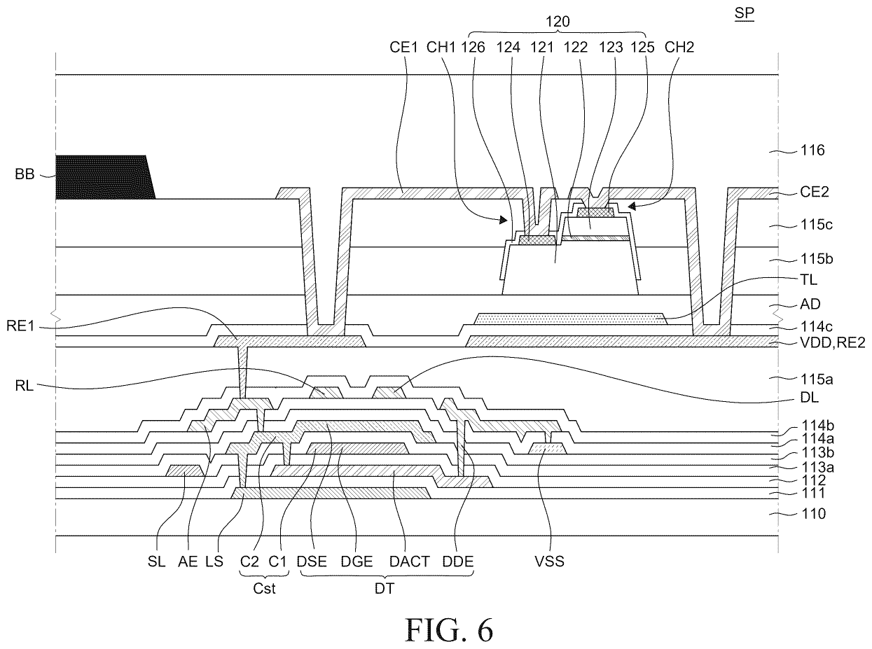

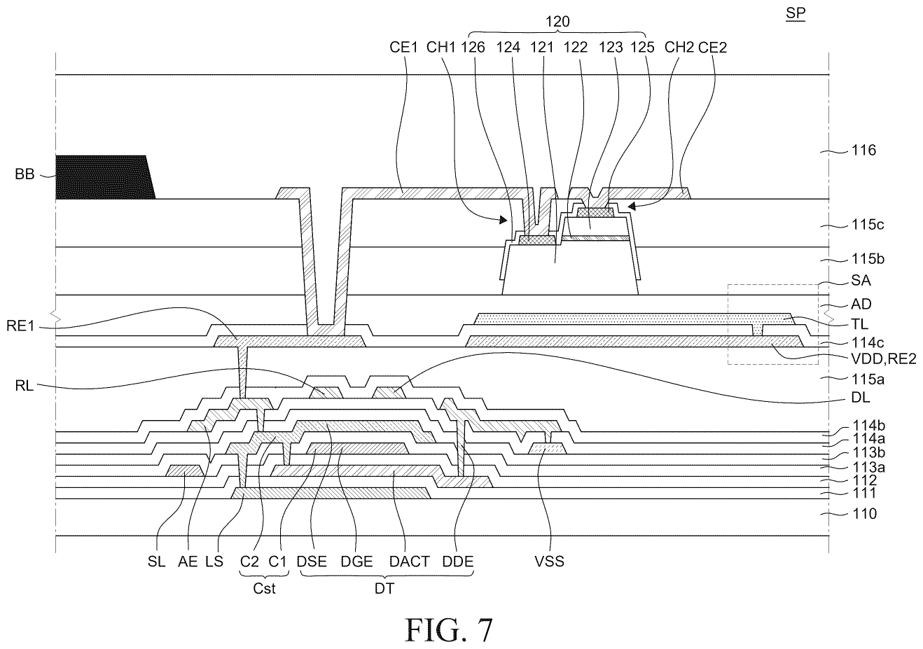

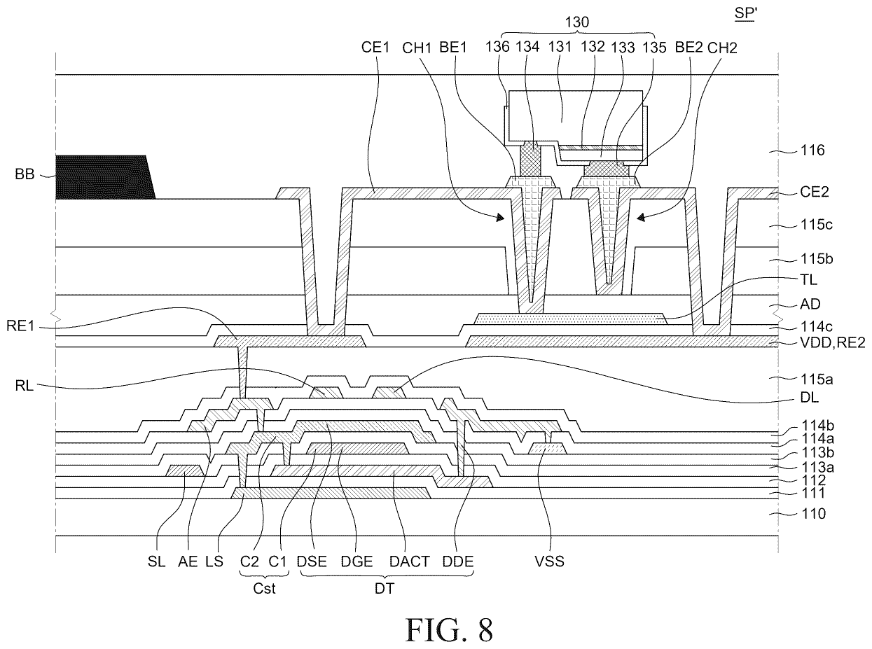

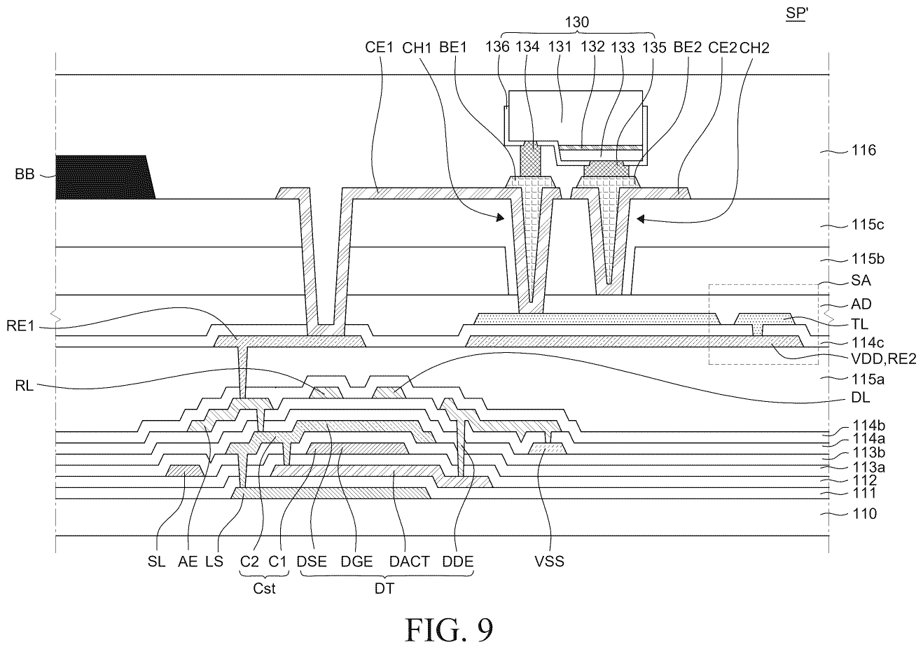

FIG. 3 is an enlarged schematic plan view of an active area of the display device according to one embodiment. FIG. 4 is a circuit diagram of a sub pixel and a repair sub pixel of the display device according to one embodiment. FIG. 5 is an enlarged plan view of area A of FIG. 3 according to one embodiment. FIGS. 6 and 7 are cross-sectional views of a sub pixel of the display device according to one embodiment. FIGS. 8 and 9 are cross-sectional views of a repair sub pixel of the display device according to one embodiment. In FIG. 3, a plurality of light emitting elements 120, a plurality of first connection electrodes CE1, and a plurality of second connection electrode CE2 are illustrated, and in FIG. 5, the first connection electrode CE1 and the second connection electrode CE2 are illustrated as a thick line, and hatching is omitted, for convenience of description.

Referring to FIG. 3, the active area AA comprises a plurality of pixel areas UPA and a plurality of transmittance areas TA. In one embodiment, a transmittance area TA is more transmissive of external light than a pixel area UPA.

In the active area AA, the plurality of pixel areas UPA are formed. In the plurality of pixel areas UPA, pixels PX are disposed and an image is displayed. The plurality of pixel areas UPA may be disposed in such a way that the plurality of pixel areas UPA are spaced from each other with the plurality of transmittance areas TA therebetween. For example, the plurality of pixel areas UPA may be disposed while forming a plurality of rows and a plurality of columns.

A plurality of sub pixels SP constituting a pixel PX is disposed in each of the plurality of pixel areas UPA. Each of the plurality of sub pixels SP may comprise a light emitting element 120 and a pixel PX circuit, and emit light independently. For example, the plurality of sub pixels SP may comprise a first sub pixel SP1, a second sub pixel SP2, and a third sub pixel SP3 that emit light of different colors. For example, the first sub pixel SP1 may be a red sub pixel SP that emits red light, the second sub pixel SP2 may be a green sub pixel SP that emits green light, and the third sub pixel SP3 may be a blue sub pixel SP that emits blue light, but not limited thereto.

Hereinafter, suppose that one pixel PX comprises two first sub pixels SP1, two second sub pixels SP2 and two third sub pixels SP3, i.e., two red sub pixels SP, two green sub pixels SP and two blue sub pixels SP, but the configuration of the pixel PX is not limited thereto.

The plurality of sub pixels SP constituting one pixel PX may be disposed in line along a column direction. The plurality of sub pixels SP may be disposed along the column direction, and overlap lines extending in the column direction. For example, the plurality of sub pixels SP may overlap a data line DL, a reference line RL, a high potential power line VDD, a low potential power line VSS and the like that extend in the column direction. The pixel area UPA is formed in an area where a plurality of opaque lines are disposed, to secure the surface area of the transmittance area TA in the entire active area AA. The pixel area UPA where the plurality of sub pixels SP are disposed may be an area that has low transmittance of light compared to the transmittance area TA and is substantially opaque because of components such as a pixel PX circuit and a light emitting element 120 and the like disposed in the plurality of sub pixels SP. Therefore, the plurality of sub pixels SP of the pixel area UPA may be disposed to overlap opaque lines, e.g., a data line DL, a reference line RL, a low potential power line VSS and a high potential power line VDD that extend in the column direction. Accordingly, the plurality of sub pixels SP of the pixel area UPA are disposed to overlap the plurality of lines, so that the surface area of an opaque area in the entire active area AA may be minimized while the surface area of the transmittance area TA may be maximized.

The plurality of sub pixels SP forming one pixel PX may be disposed in line along the column direction. For example, along the column direction, the first sub pixel SP1, the second sub pixel SP2, the third sub pixel SP3, the first sub pixel SP1, the second sub pixel SP2 and the third sub pixel SP3 are disposed consecutively. However, the order of disposing the sub pixels SP is described as an example, and not limited thereto.

Additionally, a non-transfer failure of the light emitting element 120 may occur in at least a part of the plurality of sub pixels SP. At this time, in the display device 100 of one embodiment, an additional light emitting element 130 is transferred to a defective sub pixel SP to repair the defective sub pixel SP, thereby ensuring improvement in the yield of the display device 100. To this end, the plurality of sub pixels SP may comprise a first sub pixel SP1, a second sub pixel SP2, a third sub pixel SP3, and a repair sub pixel SP′ that operates normally through a repair process. For example, in the case where the third sub pixel SP3 fails among the plurality of sub pixels SP in area A, the third sub pixel SP3 may be repaired to form a third repair sub pixel SP3′. Accordingly, a pixel PX in area A may be comprised of a pair of first sub pixels SP1, a pair of second sub pixels SP2, a third sub pixel SP3, and a third repair sub pixel SP′.

The plurality of transmittance areas TA is an area that has relatively high transmittance and lacks an area where the plurality of lines and the plurality of pixel areas UPA are disposed. In the transmittance area TA, light is transmitted, and from the front surface of the display device 100, a background on the back surface of the display device 100 may be seen. The plurality of transmittance areas TA may be disposed in such a way that the plurality of transmittance areas TA is spaced from each other with the plurality of lines and the plurality of pixel areas UPA therebetween. The plurality of transmittance areas TA may be disposed to surround the plurality of pixel areas UPA. Accordingly, the display device 100 of one embodiment may comprise a plurality of transmittance areas TA and be embodied as a transparent display device 100.

Referring to FIGS. 4-6, each of the plurality of sub pixels SP comprises a pixel PX circuit and a light emitting element 120. The pixel PX circuit may comprise a plurality of transistors T1, T2, DT, and storage capacitors Cst to drive the light emitting element 120. For example, the pixel PX circuit may comprise a first transistor T1, a second transistor T2, a driving transistor DT, and a storage capacitor Cst. Additionally, the plurality of sub pixels SP disposed in one pixel area UPA may connect to the scan line SL, and the plurality of data lines DL, the plurality of reference lines RL, the plurality of high potential power lines VDD and the plurality of low potential power lines VSS to receive various types of signals.

The substrate 110 as a component for supporting a variety of components included in the display device 100 may be formed of an insulation material. For example, the substrate 110 may be made of glass or resin and the like. Additionally, the substrate 110 may be comprised of polymer or plastics, or a material having flexibility.

On the substrate 110, a light shielding layer LS is disposed in each of the plurality of sub pixels SP. The light shielding layer LS shields light input from the lower portion of the substrate 110 to a driving active layer DACT of the driving transistor DT described hereinafter. Since light input from the light shielding layer LS to the driving active layer DACT of the driving transistor DT is shielded, thereby minimizing or at least reducing current leakage.

A buffer layer 111 is disposed on the substrate 110 and the light shielding layer LS. The buffer layer 111 may reduce the infiltration of moisture or impurities through the substrate 110. The buffer layer 111, for example, may be formed of a single layer of silicon oxide (SiOx) or silicon nitride (SiNx) or multiple layers of silicon oxide (SiOx) or silicon nitride (SiNx), but not limited thereto. However, the buffer layer 111 may be omitted depending on the sort of substrate 110 or transistor, and not limited thereto.

On the buffer layer 111, the driving transistor DT, the first transistor T1 and the second transistor T2 are disposed in each of the plurality of sub pixels SP.

The driving transistor DT, the first transistor T1 and the second transistor T2 of each of the plurality of sub pixels SP may be a P-type thin film transistor or an N-type thin film transistor. For example, in the case of a P-type thin film transistor, since a hole moves from a source electrode to a drain electrode, current may flow from the source electrode to the drain electrode. In the case of an N-type thin film transistor, since an electron moves from a source electrode to a drain electrode, current may flow from the drain electrode to the source electrode. Hereinafter, suppose that the driving transistor DT, the first transistor T1 and the second transistor T2 are a P-type thin film transistor where current flows from a source electrode to a drain electrode, but not be limited thereto.

On the buffer layer 111, the driving transistor DT is disposed in each of the plurality of sub pixels SP. The driving transistor DT is a transistor for controlling driving current supplied to the light emitting element 120. In one pixel area UPA, the driving transistor DT of each of the plurality of sub pixels SP may be disposed in line along the column direction. The plurality of driving transistors DT of the plurality of sub pixels SP may be disposed in line while overlapping the area where the reference line RL and the data line DL are disposed.

The driving transistor DT comprises a driving active layer DACT, a driving gate electrode DGE, a driving source electrode DSE and a driving drain electrode DDE.

The driving active layer DACT is disposed on the buffer layer 111. The driving active layer DACT may be formed of a semiconductor material such as oxide semiconductor, amorphous silicon or polysilicon, but not limited thereto.

A gate insulation layer 112 is disposed on the driving active layer DACT. The gate insulation layer 112, as an insulation layer for insulating the driving active layer DACT and the driving gate electrode DGE, may be comprised of a single layer of silicon oxide (SiOx) or silicon nitride (SiNx) or multiple layers of silicon oxide (SiOx) or silicon nitride (SiNx), but not limited thereto.

The driving gate electrode DGE is disposed on the gate insulation layer 112. The driving gate electrode DGE may be made of a conductive material, e.g., copper (Cu), aluminum (Al), molybdenum (Mo), nickel (Ni), titanium (Ti), chromium (Cr), or an alloy thereof, but not limited thereto.

A first interlayer insulation layer 113a is disposed on the driving gate electrode DGE. The first interlayer insulation layer 113a has a contact hole for connecting the driving source electrode DSE to the driving active layer DACT. The first interlayer insulation layer 113a, as an insulation layer for protecting components thereunder, may be comprised of a single layer of silicon oxide (SiOx) or silicon nitride (SiNx) or multiple layers of silicon oxide (SiOx) or silicon nitride (SiNx), but not limited thereto.

The driving source electrode DSE is disposed on the first interlayer insulation layer 113a. In one embodiment, the driving source electrode DSE overlaps the driving gate electrode DGE. The driving source electrode DSE is electrically connected to the driving active layer DACT through a contact hole formed at the first interlayer insulation layer 113a and the gate insulation layer 112. Additionally, the driving source electrode DSE may be electrically connected to the second transistor T2. The driving source electrode DSE may be made of a conductive material, e.g., copper (Cu), aluminum (Al), molybdenum (Mo), nickel (Ni), titanium (Ti), chromium (Cr), or an alloy thereof, but not limited thereto.

On the first interlayer insulation layer 113a, a second interlayer insulation layer 113b and a first passivation layer 114a are disposed, and on the first passivation layer 114a, the driving drain electrode DDE is disposed. The driving drain electrode DDE may be electrically connected to the driving active layer DACT through a contact hole formed at the first passivation layer 114a, the second interlayer insulation layer 113b, the first interlayer insulation layer 113a, and the gate insulation layer 112. Additionally, the driving drain electrode DDE may be electrically connected to the low potential power line VSS through the contact hole formed at the first passivation layer 114a. The driving drain electrode DDE may be made of a conductive material, e.g., copper (Cu), aluminum (Al), molybdenum (Mo), nickel (Ni), titanium (Ti), chromium (Cr), or an alloy thereof, but not limited thereto.

Then the first transistor T1 is disposed in each of the plurality of sub pixels SP, on the buffer layer 111. The first transistor T1, as a transistor delivering a data voltage to the driving gate electrode DGE of the driving transistor DT, may be referred to as a switching transistor. At this time, in one pixel area UPA, a plurality of first transistors T1 of the plurality of sub pixels SP may overlap the scan line SL, and disposed in line along a row direction.

Specifically, the scan line SL may be disposed across the plurality of pixel areas UPA while extending in the row direction on the gate insulation layer 112. Additionally, from the left, the first transistor T1 of the first sub pixel SP1 at the other side of the scan line SL, the first transistor T1 of the other first sub pixel SP1 at one side of the scan line SL, the first transistor T1 of the second sub pixel SP2 at the other side of the scan line SL, the first transistor T1 of the other second sub pixel SP2 at one side of the scan line SL, the first transistor T1 of the third sub pixel SP3 at the other side of the scan line SL, and the first transistor T1 of the other third sub pixel SP3 at one side of the scan line SL may be disposed consecutively.

At this time, the first transistors T1 of a pair of first sub pixels SP1 may be disposed to be adjacent to each other and share one data line DL. Further, the first transistors T1 of a pair of second sub pixels SP2 may be disposed to be adjacent to each other and share one data line DL. Furthermore, the first transistors T1 of a pair of third sub pixels SP3 may also be disposed to be adjacent to each other and share one data line DL.

The first transistor T1 comprises a first active layer ACT1, a first gate electrode GE1, a first source electrode SE1, and a first drain electrode DE1.

The first active layer ACT1 is disposed on the buffer layer 111. The first active layer ACT1 may be made of a semiconductor material such as oxide semiconductor, amorphous silicon or polysilicon, but not limited thereto.

The first gate electrode GE1 is disposed on the gate insulation layer 112. The first gate electrode GE1 may be electrically connected to the scan line SL. For example, the first gate electrode GE1 may be integrated with the scan line SL. The first gate electrode GE1 may be made of a conductive material, e.g., copper (Cu), aluminum (Al), molybdenum (Mo), nickel (Ni), titanium (Ti), chromium (Cr), or an alloy thereof, but not limited thereto.

The first drain electrode DE1 is disposed on the first interlayer insulation layer 113a. The first drain electrode DE1 may be electrically connected to the first active layer ACT1 through the contact hole formed at the first interlayer insulation layer 113a and the gate insulation layer 112. Additionally, the first drain electrode DE1 may also be electrically connected to a second gate electrode GE2 of the second transistor T2 through the contact hole of the first interlayer insulation layer 113a. The first drain electrode DE1 may be made of a conductive material, e.g., copper (Cu), aluminum (Al), molybdenum (Mo), nickel (Ni), titanium (Ti), chromium (Cr), or an alloy thereof, but not limited thereto.

The second interlayer insulation layer 113b is disposed on the first drain electrode DE1. The second interlayer insulation layer 113b, as an insulation layer for protecting components thereunder, may be comprised of a single layer of silicon oxide (SiOx) or silicon nitride (SiNx) or multiple layers of silicon oxide (SiOx) or silicon nitride (SiNx), but not limited thereto.

The first passivation layer 114a is disposed on the second interlayer insulation layer 113b. The first passivation layer 114a, as an insulation layer for protecting components thereunder, may be comprised of a single layer of silicon oxide (SiOx) or silicon nitride (SiNx) or multiple layers of silicon oxide (SiOx) or silicon nitride (SiNx), but not limited thereto.

The first source electrode SE1 is disposed on the first passivation layer 114a. The first source electrode SE1 may be electrically connected to the first active layer ACT1 through the contact hole of the first passivation layer 114a, the second interlayer insulation layer 113b and the first interlayer insulation layer 113a. Additionally, the first source electrode SE1 may be electrically connected to the data line DL. For example, the first source electrode SE1 may be integrated with the data line DL. The first source electrode SE1 may be made of a conductive material, e.g., copper (Cu), aluminum (Al), molybdenum (Mo), nickel (Ni), titanium (Ti), chromium (Cr), or an alloy thereof, but not limited thereto.

Then the second transistor T2 is disposed in each of the plurality of sub pixels SP, on the buffer layer 111. The second transistor T2, as a transistor for compensating a threshold voltage of the driving transistor DT, may be referred to as a sensing transistor. The second transistor T2 of the plurality of sub pixels SP may be disposed at the left side of each of the plurality of sub pixels SP, and disposed in line along the column direction.

For example, the scan line SL may comprise a portion protruding in the column direction from a portion extending in the row direction. The portion of the scan line SL, protruding in the column direction, may be disposed near the left side of the plurality of sub pixels SP and overlap a plurality of second transistors T2. The portion of the scan line SL, protruding in the column direction, may function as the second gate electrode GE2 of the second transistor T2 of the plurality of sub pixels SP. Accordingly, the second transistor T2 of the plurality of sub pixels SP may be disposed on the protruding portion of the scan line SL and disposed in line in the column direction.

The second transistor T2 comprises a second active layer ACT2, a second gate electrode GE2, a second source electrode SE2 and a second drain electrode DE2.

The second active layer ACT2 is disposed between the buffer layer 111 and the gate insulation layer 112. The second active layer ACT2 may be made of a semiconductor material such as oxide semiconductor, amorphous silicon or polysilicon, but not limited thereto.

At this time, the second active layers ACT2 of mutually adjacent sub pixels SP may connect to each other. For example, the second active layers ACT2 of the first sub pixel SP1, the second sub pixel SP2 and the third sub pixel SP3 disposed at one side of the scan line SL may connect to each other while extending in the column direction, and together, connect to the second drain electrode DE2 disposed in the first sub pixel SP1. Additionally, the second active layers ACT2 of the first sub pixel SP1, the second sub pixel SP2 and the third sub pixel SP3 disposed at the other side of the scan line SL may also connect to each other while extending in the column direction, and together, connect to the second drain electrode DE2 disposed in the first sub pixel SP1.

That is, a portion where a channel area of the second active layer ACT2 of the plurality of sub pixels SP connects with the reference line RL is made of a material of a transparent second active layer ACT2 rather than an opaque conductive material, so that transmittance in an outermost side of the pixel area UPA may improve. Additionally, the portion where the channel area of the second active layer ACT2 of the plurality of sub pixels SP connects with the reference line RL is made of a material of the second active layer ACT2, to delete the contact hole and simplify the structure of the pixel area UPA.

The gate electrode GE2 is disposed between the gate insulation layer 112 and the first interlayer insulation layer 113a. The second gate electrode GE2 may be electrically connected to the scan line SL. For example, the second gate electrode GE2 may be integrated with and electrically connected to the protruding portion of the scan line SL. The second gate electrode GE2 may be made of a conductive material, e.g., copper (Cu), aluminum (Al), molybdenum (Mo), nickel (Ni), titanium (Ti), chromium (Cr), or an alloy thereof, but not limited thereto.

The second source electrode SE2 is disposed between the first interlayer insulation layer 113a and the second interlayer insulation layer 113b. The second source electrode SE2 may be electrically connected to the second active layer ACT2 through the contact holes of the first interlayer insulation layer 113a and the gate insulation layer 112. Additionally, the second source electrode SE2 may electrically connect to the driving source electrode DSE. The second source electrode SE2 may be made of a conductive material, e.g., copper (Cu), aluminum (Al), molybdenum (Mo), nickel (Ni), titanium (Ti), chromium (Cr), or an alloy thereof, but not limited thereto.

The second drain electrode DE2 is disposed between the first passivation layer 114a and the second passivation layer 114b. The second drain electrode DE2 may be electrically connected to the second active layer ACT2 through the contact holes formed at the first passivation layer 114a, the second interlayer insulation layer 113b, the first interlayer insulation layer 113a and the gate insulation layer 112. The second drain electrode DE2 may be integrated with the reference line RL and electrically connected to the reference line RL. The second drain electrode DE2 may be made of a conductive material, e.g., copper (Cu), aluminum (Al), molybdenum (Mo), nickel (Ni), titanium (Ti), chromium (Cr), or an alloy thereof, but not limited thereto.

Then the storage capacitor Cst is disposed on the gate insulation layer 112. The storage capacitor Cst may store a potential difference between the driving gate electrode DGE and the driving source electrode DSE of the driving transistor DT while the light emitting element 120 emits light, so that constant driving current may be supplied to the light emitting element 120. The storage capacitor Cst may comprise a first capacitor electrode C1 electrically connected to the driving gate electrode DGE, and a second capacitor electrode C2 electrically connected to the driving source electrode DSE, to keep the voltage of the driving gate electrode DGE and the driving source electrode DSE constant.

Specifically, the first capacitor electrode C1 is disposed on the gate insulation layer 112. The first capacitor electrode C1 may be integrated with the driving gate electrode DGE. The second capacitor electrode C2 is disposed on the first interlayer insulation layer 113a. The first capacitor electrode C1 and the second capacitor electrode C2 may be disposed to overlap each other with the first interlayer insulation layer 113a therebetween. At this time, the second capacitor electrode C2 may be integrated with the driving source electrode DSE. The first capacitor electrode C1 and the second capacitor electrode C2 may be made of a conductive material, e.g., copper (Cu), aluminum (Al), molybdenum (Mo), nickel (Ni), titanium (Ti), chromium (Cr), or an alloy thereof, but not limited thereto.

Then an auxiliary electrode AE is disposed on the first passivation layer 114a. The auxiliary electrode AE is an electrode for electrically connecting the driving source electrode DSE and a first reflective electrode RE1. The driving source electrode DSE and the first reflective electrode RE1 may be electrically connected to each other through the auxiliary electrode AE. The auxiliary electrode AE may be made of a conductive material, e.g., copper (Cu), aluminum (Al), molybdenum (Mo), nickel (Ni), titanium (Ti), chromium (Cr), or an alloy thereof, but not limited thereto.

The low potential power line VSS is disposed on the second interlayer insulation layer 113b. The low potential power line VSS is disposed along the column direction, and overlap the plurality of pixel areas UPA. The low potential power line VSS may be electrically connected to the driving drain electrode DDE. The low potential power line VSS may be made of a conductive material, e.g., copper (Cu), aluminum (Al), molybdenum (Mo), nickel (Ni), titanium (Ti), chromium (Cr), or an alloy thereof, but not limited thereto.

The reference line RL is disposed on the first passivation layer 114a. The reference line RL may be disposed along the column direction and overlap the plurality of pixel areas UPA. The reference line RL may be disposed near the plurality of second transistors T2 and electrically connected to the plurality of second transistors T2. The reference line RL may be made of a conductive material, e.g., copper (Cu), aluminum (Al), molybdenum (Mo), nickel (Ni), titanium (Ti), chromium (Cr), or an alloy thereof, but not limited thereto.

The plurality of data lines DL are disposed on the first passivation layer 114a. The plurality of data lines DL may overlap the plurality of pixel areas UPA while extending in the column direction. The plurality of data lines DL may comprise a data line DL connecting to the first transistor T1 of the plurality of first sub pixels SP1, a data line DL connecting to the first transistor T1 of the plurality of second sub pixels SP2, and a data line DL connecting to the first transistor T1 of the plurality of third sub pixels SP3. For example, from the left, the reference line RL, the data line DL connecting to the first sub pixel SP1, the data line DL connecting to the second sub pixel SP2, and the data line DL connecting to the third sub pixel SP3 may be disposed consecutively.

Then, the second passivation layer 114b is disposed on the driving transistor DT, the first transistor T1, the second transistor T2, the storage capacitor Cst, the reference line RL and the data line DL. The second passivation layer 114b, as an insulation layer for protecting components thereunder, may be comprised of a single layer of silicon oxide (SiOx) or silicon nitride (SiNx) or multiple layers of silicon oxide (SiOx) or silicon nitride (SiNx), but not limited thereto.

A first planarization layer 115a is disposed on the second passivation layer 114b. The first planarization layer 115a may planarize the upper portion of the substrate 110 where the plurality of transistors and storage capacitors Cst are disposed. The first planarization layer 115a may be comprised of a single layer or multiple layers, and for example, may be made of photoresist or an acryl-based organic material, but not limited thereto.

Further, though not illustrated in the drawings, an additional passivation layer may be disposed on the first planarization layer 115a. For example, a passivation layer comprised of a single layer of silicon oxide (SiOx) or silicon nitride (SiNx) or multiple layers of silicon oxide (SiOx) or silicon nitride (SiNx) is formed on the first planarization layer 115a to protect components thereunder.

Then a plurality of first reflective electrodes RE1 are disposed on the first planarization layer 115a. Each of the plurality of first reflective electrodes RE1 may be disposed in a corresponding one of the plurality of sub pixels SP, and reflect light emitting from the light emitting element 120 of the sub pixel SP to the outside of the display device 100 at the same time as the first reflective electrode RE1 electrically connects the driving transistor DT and the light emitting element 120. The plurality of first reflective electrodes RE1 may be disposed near the driving source electrode DSE, in each of the plurality of sub pixels SP. The plurality of first reflective electrodes RE1 may be made of a conductive opaque material such as titanium (Ti), gold (Au), silver (Ag), copper (Cu), or an alloy thereof having high reflection efficiency, but not limited thereto.

On the first planarization layer 115a, the high potential power line VDD that is a second reflective electrode RE2 is disposed. The second reflective electrode RE2 and the high potential power line VDD may be integrated, and reflect light emitting from the light emitting element 120 to the outside of the display device 100 while providing a high potential power voltage to the light emitting element 120. The second reflective electrode RE2 of each of the plurality of sub pixels SP may be connected mutually and integrally formed. The second reflective electrode RE2 and the high potential power line VDD may extend in the column direction and be disposed to overlap the light emitting element 120. The second reflective electrode RE2 and the high potential power line VDD may be disposed to overlap the plurality of data lines DL, the reference line RL and the low potential power line VSS. The second reflective electrode RE2 and the high potential power line VDD may be made of a conductive opaque material such as titanium (Ti), gold (Au), silver (Ag), copper (Cu), or an alloy thereof having high reflection efficiency, but not limited thereto.

Further, the second reflective electrode RE2 may protrude toward a first area SA, in each of the plurality of sub pixels SP. The second reflective electrode RE2 may comprise a portion protruding toward the right side of each of the plurality of sub pixels SP. The protruding portion of the second reflective electrode RE2 may overlap the first area SA at the right side of the plurality of sub pixels SP.

Then a third passivation layer 114c is disposed on the plurality of first reflective electrodes RE1 and the plurality of second reflective electrodes RE2. The third passivation layer 114c, as an insulation layer for protecting components thereunder, may be comprised of a single layer of silicon oxide (SiOx) or silicon nitride (SiNx) or multiple layers of silicon oxide (SiOx) or silicon nitride (SiNx), but not limited thereto.

Referring to FIGS. 6 and 7, a sensing layer TL is disposed on the third passivation layer 114c in each of the plurality of sub pixels SP. That is, a plurality of sensing layers TL are on the third passivation layer 114c and each sensing layer TL is in a corresponding one of the plurality of sub pixels SP. In one embodiment, the third passivation layer 114c is between the sensing layer TL and the second reflective electrode RE2. Each sensing layer TL may overlap the area where a light emitting element 120 is disposed. Thus, the sensing layer TL may overlap the plurality of light emitting elements 120. Each sensing layer TL is a layer for sensing a non-transfer failure of a light emitting element from the plurality of light emitting elements 120. That is, the sensing layers TL are for sensing a failure of transferring light emitting elements 120.

Each sensing layer TL may protrude toward the first area SA at one side of each of the plurality of sub pixels SP from the area where the plurality of light emitting elements 120 are disposed. For example, a sensing layer TL may comprise a portion protruding toward the right side of the plurality of sub pixels SP. Additionally, the protruding portion of the sensing layer TL may overlap the first area SA. In the first area SA, the protruding portion of the sensing layer TL and the protruding portion of the second reflective electrode RE2 may be electrically connected to each other through a contact hole formed at the third passivation layer 114c. Accordingly, since in a normal sub pixel SP, the sensing layer TL connects to the high potential power line VDD that is the second reflective electrode RE2, the sensing layer TL may be in the state where a high potential power voltage is supplied to the sensing layer TL.

The sensing layer TL may be made of any one of a conductive material, e.g., copper (Cu), aluminum (Al), molybdenum (Mo), nickel (Ni), titanium (Ti), chromium (Cr) or an alloy thereof, or a conductive transparent material such as indium tin oxide (ITO) or indium zinc oxide (IZO) and the like, but not limited thereto.

On the third passivation layer 114c and the sensing layer TL, an adhesive layer AD is disposed. The adhesive layer AD may be formed on the front surface of the substrate 110 and fix the light emitting element 120 disposed on the adhesive layer AD. The adhesive layer AD is between the sensing layers TL and the light emitting elements 120. The adhesive layer AD may be made of a photocurable adhesive material that is curable by light. For example, the adhesive layer AD may be selected from any one of adhesive polymer, epoxy resist, UV resin, a polyimide-based one, an acrylate-based one, a urethane-based one, and polydimethylsiloxane (PDMS), but not limited thereto.

On the adhesive layer AD, the plurality of light emitting elements 120 are disposed in the plurality of sub pixels SP. That is, each light emitting element 120 is disposed in a corresponding sub pixel SP. Additionally, an additional light emitting element 130 is disposed in the repair sub pixel SP′. The light emitting element 120, as an element emitting light with current, may comprise a red light emitting element 120R emitting red light, a green light emitting element 120G emitting green light, or a blue light emitting element 120B emitting blue light, and a combination of the light-emitting elements 120 may implement various colors including white. The additional light emitting element 130 may also be an element substantially the same as the light emitting element 120, and comprise a variety of additional light emitting elements 130 emitting red light, green light or blue light. For example, the light emitting element 120 and the additional light emitting element 130 may be a light emitting diode (LED) or a micro LED, but not limited thereto.

The red light emitting element 120R may be disposed in the first sub pixel SP1, the green light emitting element 120G may be disposed in the second sub pixel SP2, and the blue light emitting element 120b may be disposed in the third sub pixel SP3. The plurality of light emitting elements 120 disposed in one pixel area UPA may be disposed in line along the column direction. Additionally, in each of the plurality of sub pixels SP, the plurality of light emitting elements 120 may be disposed to overlap the second reflective electrode RE2.

Referring to FIGS. 6 and 7, each of the plurality of light emitting elements 120 comprises a first semiconductor layer 121, a light emitting layer 122, a second semiconductor layer 123, a first electrode 124, a second electrode 125 and an encapsulation film 126.

The first semiconductor layer 121 is disposed on the adhesive layer AD, and the second semiconductor layer 123 is disposed on the first semiconductor layer 121. The first semiconductor layer 121 and the second semiconductor layer 123 may be formed in such a way that n-type and p-type impurities are doped on a specific material. For example, each of the first semiconductor layer 121 and the second semiconductor layer 123 may be layers where n-type and p-type impurities are doped on a material such as gallium nitride (GaN), indium aluminum phosphide (InAlP), gallium arsenide (GaAs) and the like. Additionally, the p-type impurities may be magnesium, zinc (Zn), beryllium (Be) and the like, and the n-type impurities may be silicon (Si), germanium, tin (Sn) and the like, but not limited thereto.

The light emitting layer 122 is disposed between the first semiconductor layer 121 and the second semiconductor layer 123. The light emitting layer 122 may receive holes and electrons from the first semiconductor layer 121 and the second semiconductor layer 123 to emit light. The light emitting layer 122 may be structured as a single layer or a multi-quantum well (MQW), and for example, made of indium gallium nitride (InGaN) or gallium nitride (GaN) and the like, but not limited thereto.

The first electrode 124 is disposed on the first semiconductor layer 121. The first electrode 124 is an electrode for electrically connecting the driving transistor DT and the first semiconductor layer 121. At this time, the first semiconductor layer 121 may be a semiconductor layer doped with n-type impurities, and the first electrode 124 may be a cathode. The first electrode 124 may be disposed on the upper surface of the first semiconductor layer 121 exposed form the light emitting layer 122 and the second semiconductor layer 123. The first electrode 124 may be made of a conductive material, e.g., a conductive transparent material such as indium tin oxide (ITO) or indium zinc oxide (IZO) and the like or a conductive opaque material such as titanium (Ti), gold (Au), silver (Ag), copper (Cu), or an alloy thereof, and the like but not limited thereto.

The second electrode 125 is disposed on the second semiconductor layer 123. The second electrode 125 is an electrode for electrically connecting the high potential power line VDD and the second semiconductor layer 123. At this time, the second semiconductor layer 123 may be a semiconductor layer doped with p-type impurities, and the second electrode 125 may be an anode. The second electrode 125 may be made of a conductive material, e.g., a conductive transparent material such as indium tin oxide (ITO) or indium zinc oxide (IZO) and the like or a conductive opaque material such as titanium (Ti), gold (Au), silver (Ag), copper (Cu), or an alloy thereof, and the like, but not limited thereto.

Then the encapsulation film 126 surrounding the first semiconductor layer 121, the light emitting layer 122, the second semiconductor layer 123, the first electrode 124 and the second electrode 125 is disposed. The encapsulation film 126 may be made of an insulation material, and protect the first semiconductor layer 121, the light emitting layer 122 and the second semiconductor layer 123. Additionally, the encapsulation film 126 has a contact hole exposing the first electrode 124 and the second electrode 125, so that the first connection electrode CE1 and the second connection electrode CE2 may be electrically connected to the first electrode 124 and the second electrode 125, respectively.

Further, a portion of the lateral surface of the first semiconductor layer 121 may be exposed from the encapsulation film 126. The light emitting element 120 manufactured on a wafer may be separated from the wafer and transferred to the display panel PN. However, in the process where the light emitting element 120 is separated from the wafer, a portion of the encapsulation film 126 may be torn off. For example, a portion of the encapsulation film 126, adjacent to the edge at the lower side of the first semiconductor layer 121 of the light emitting element 120, may be torn off in the process where the light emitting element 120 separates from the wafer, and a portion of the lateral surface at the lower side of the first semiconductor layer 121 may be exposed to the outside. Even if a portion at the lower side of the light emitting element 120 is exposed from the encapsulation film 126, a short-circuit failure may decrease, since a second planarization layer 115b and a third planarization layer 115c covering the lateral surface of the first semiconductor layer 121 are formed, and then the first connection electrode CE1 and the second connection electrode CE2 are formed.

Then the second planarization layer 115b and the third planarization layer 115c are disposed on the adhesive layer AD and the light emitting element 120. As shown in FIG. 6, the light emitting element 120 is between a portion of an insulation layer (e.g., the third planarization layer 115c) and the high potential power line VDD, RE2.

The second planarization layer 115b may overlap a portion of the side portion of the plurality of light emitting elements 120 and fix and protect the plurality of light emitting elements 120. A torn-off portion of the encapsulation film 126 protecting the lateral surface of the first semiconductor layer 121 of the light emitting element 120 may be covered by the second planarization layer 115b. Accordingly, contact between the connection electrodes and the first semiconductor layer 121 and a short-circuit failure may be prevented.

The second planarization layer 115b may comprise an opening. The opening of the second planarization layer 115b may overlap the light emitting element 120. The light emitting element 120 may be disposed in the opening of the second planarization layer 115b. The opening of the second planarization layer 115b may overlap an area where a first contact hole CH1 and a second contact hole CH2 are formed. For example, referring to FIG. 6, the first electrode 124 and the second electrode 125 of the light emitting element 120 may overlap the opening of the second planarization layer 115b. Additionally, referring to FIG. 8, in the repair sub pixel SP′ where the light emitting element 120 is not disposed, the third planarization layer 115c may be disposed instead, in the opening of the second planarization layer 115b. Thus, in a normal sub pixel SP, the light emitting element 120 is disposed in the opening of the second planarization layer 115b, and the third planarization layer 115c and the adhesive layer do not contact each other in the opening, but in the case of a repair sub pixel SP′, the light emitting element 120 is not disposed in the opening, and the third planarization layer 115c and the adhesive layer AD may contact each other in the opening of the second planarization layer 115b.

The third planarization layer 115c is formed to cover the upper side portions of the second planarization layer 115b and the light emitting element 120. The third planarization layer 115c may have a contact hole through which the first electrode 124 and the second electrode 125 of the light emitting element 120 are exposed. The first electrode 124 and the second electrode 125 of the light emitting element 120 are exposed from the third planarization layer 115c, but the third planarization layer 115c is partially disposed in an area between the first electrode 124 and the second electrode 125 to prevent a short-circuit failure. The second planarization layer 115b and the third planarization layer 115c may be comprised of a single layer or multiple layers, and for example, made of photoresist or an acryl-based organic material, but not limited thereto.

A plurality of first connection electrodes CE1 and a plurality of second connection electrodes CE2 are disposed on the third planarization layer 115c.

A first connection electrode CE1 is an electrode for electrically connecting the first electrode 124 of a corresponding light emitting element 120 and a corresponding driving transistor DT. The first connection electrode CE1 may be electrically connected to the first reflective electrode RE1 through the contact holes formed at the third planarization layer 115c, the second planarization layer 115b and the third passivation layer 114c at the same time as the first connection electrode CE1 may be electrically connected to the first electrode 124 in the first contact hole CH1 of the third planarization layer 115c. Accordingly, the first electrode 124 and the driving source electrode DSE may be electrically connected each other through the first connection electrode CE1, the first reflective electrode RE1 and the auxiliary electrode AE.

A second connection electrode CE2 may be an electrode for electrically connecting the second electrode 125 of the corresponding light emitting element 120 and the high potential power line VDD. The second connection electrode CE2 may be electrically connected to the high potential power line VDD that is the second reflective electrode RE2 through the contact holes (e.g., third contact holes) formed at the third planarization layer 115c, the second planarization layer 115b and the third passivation layer 114c. Further, the second connection electrode CE2 may be electrically connected to the second electrode 125 in the second contact hole CH2 of the third planarization layer 115c. Accordingly, the second electrode 125 and the high potential power line VDD may be electrically connected to each other through the second connection electrode CE2.

The first connection electrode CE1 and the second connection electrode CE2 may be made of a conductive transparent material such as indium tin oxide (ITO) or indium zinc oxide (IZO) and the like, but not limited thereto.

Further, in the drawings, the driving source electrode DSE of the driving transistor DT and the first electrode 124 of the light emitting element 120 are electrically connected to each other, but the driving drain electrode DDE of the driving transistor DT and the second electrode 125 of the light emitting element 120 may be electrically connected to each other depending on the type of driving transistor DT and the design of the pixel PX circuit, but not be limited thereto.

Then in the pixel area UPA, a bank BB is disposed on the third planarization layer 115c, the first connection electrode CE1 and the second connection electrode CE2. The bank BB may be spaced a predetermined distance apart from the light emitting element 120. The bank BB may be disposed at the boundary between the plurality of sub pixels SP and cover a portion of the first connection electrode CE1 and the second connection electrode CE2. The bank BB may be spaced from the transmittance area TA. The bank BB may be made of a material comprising an opaque material or a black ingredient to reduce a mixture of colors among the plurality of sub pixels SP, and for example, made of black resin, but not limited thereto.

A protective layer 116 is disposed on the first connection electrode CE1, the second connection electrode CE2 and the bank BB. The protective layer 116 is a layer for protecting components thereunder. The protective layer 116 may be comprised of a single layer or multiple layers, and for example, made of benzocyclobutene, translucent epoxy, photoresist or an acryl-based organic material or an inorganic material such as silicon oxide (SiOx) or silicon nitride (SiNx), and the like, but not limited thereto.

Referring to FIG. 8, the additional light emitting element 130 is disposed instead of the light emitting element 120, in the repair sub pixel SP′. As shown in FIG. 8, the additional light emitting element 130 farther from the substrate 110 than the light emitting element 120 and is on the third planarization layer 115c (e.g., an insulation layer) such that the third planarization layer 115c is between the additional light emitting element 130 and the high potential power line VDD, RE2. During the process of manufacturing the display device 100, a lighting test process of the sub pixel SP may be performed after the formation of up to the first connection electrode CE1 and the second connection electrode CE2. At this time, in a defective sub pixel SP to which the light emitting element 120 is not transferred, the additional light emitting element 130 is transferred onto the first connection electrode CE1 and the second connection electrode CE2 to repair the defective sub pixel SP. For example, an additional light emitting element 130 emitting red light may be transferred to a defective sub pixel SP to which the red light emitting element 120R is not transferred, an additional light emitting element 130 emitting green light may be transferred to a defective sub pixel SPG to which the green light emitting element 120G is not transferred, and an additional light emitting element 130 emitting blue light may be transferred to a defective sub pixel SP to which the blue light emitting element 120B is not transferred.

First, in the repair sub pixel SP′, a first bonding electrode BE1 is disposed on the first connection electrode CE1 of the repair sub pixel SP′. The first bonding electrode BE1 is an electrode for electrically connecting the additional light emitting element 130 and the first connection electrode CE1. The first bonding electrode BE1 may be disposed in the first contact hole CH1 where the first connection electrode CE1 is formed. The first bonding electrode BE1 may be disposed to fill the first contact hole CH1, and protrude toward the upper portion of the first connection electrode CE1.

In the repair sub pixel SP′, a second bonding electrode BE2 is disposed on the second connection electrode CE2. The second bonding electrode BE2 is an electrode for electrically connecting the additional light emitting element 130 and the second connection electrode CE2. The second bonding electrode BE2 may be disposed in the second contact hole CH2 where the second connection electrode CE2 is formed. The second bonding electrode BE2 may be disposed to fill the second contact hole CH2, and protrude toward the upper portion of the second connection electrode CE2.

The first bonding electrode BE1 and the second bonding electrode BE2 may be made of a conductive material that adhesively bonds the additional light emitting element 130 onto the first connection electrode CE1 and the second connection electrode CE2 and has high reflectance. For example, the first bonding electrode BE1 and the second bonding electrode BE2 may be made of silver paste (Ag paste) or indium and the like.

Further, the first bonding electrode BE1 and the second bonding electrode BE2 may connect the additional light emitting element 130 to the first connection electrode CE1 and the second connection electrode CE2 at the same time as the first bonding electrode BE1 and the second bonding electrode BE2 are respectively configured to fill the air gaps of the first contact hole CH1 and the second contact hole CH2. Specifically, at a time of manufacturing the display device 100, in the process of forming the first contact hole CH1 and the second contact hole CH2 at the third planarization layer 115c to expose the first electrode 124 and the second electrode 125 of the light emitting element 120, a defective sub pixel SP to which the light emitting element 120 is not transferred also has a first contact hole CH1 and a second contact hole CH2. Accordingly, in the defective sub pixel SP, grooves may be formed by the first contact hole CH1 and the second contact hole CH2 at the third planarization layer 115c.

Further, after the first contact hole CH1 and the second contact hole CH2 are formed, a conductive layer may be formed on the front surface of the substrate 110, and patterned to form the first connection electrode CE1 and the second connection electrode CE2. In a defective sub pixel SP, the first connection electrode CE1 and the second connection electrode CE2 are respectively shaped to correspond to the shapes of the first contact hole CH1 and the second contact hole CH2, so that the first connection electrode CE1 and the second connection electrode CE2 are formed concavely.

However, in the case where the additional light emitting element 130 is disposed immediately on the first connection electrode CE1 and the second connection electrode CE2 formed concavely by the grooves, an air gap may be formed in the concave portions of the first connection electrode CE1 and the second connection electrode CE2. Since the first connection electrode CE1 and the second connection electrode CE2 are not formed planarly, a first additional electrode 134 and a second additional electrode 135 of the additional light emitting element 130 may not properly connect to the first connection electrode CE1 and the second connection electrode CE2, and an air gap in which oxygen or moisture is present may be formed in the grooves, causing a failure where a variety of metallic layers in the display panel PN is oxidated.

Therefore, in the display device 100 of one embodiment, the first bonding electrode BE1 and the second bonding electrode BE2 filling the concave portions of the first connection electrode CE1 and the second connection electrode CE2 respectively disposed in the first contact hole CH1 and the second contact hole CH2 are formed to remove the air gaps. Additionally, the additional light emitting element 130 may be readily attached and fixed onto the first bonding electrode BE1 and the second bonding electrode BE2 that have a planar upper surface, and electrically connected to the first connection electrode CE1 and the second connection electrode CE2, thereby minimizing a lighting failure of the additional light emitting element 130. Further, the first bonding electrode BE1 and the second bonding electrode BE2 may be formed of a conductive material having high reflectance, and reflect light emitting from the additional light emitting element 130 to the upper portion of the display panel PN. Thus, the first bonding electrode BE1 and the second bonding electrode BE2 may function as a reflective layer, thereby enhancing light efficiency of the display device 100.

The additional light emitting element 130 is disposed on the first bonding electrode BE1 and the second bonding electrode BE2. The additional light emitting element 130 comprises a first additional semiconductor layer 131, an additional light emitting layer 132, a second additional semiconductor layer 133, a first additional electrode 134, a second additional electrode 135, and an additional encapsulation film 136.

The second additional semiconductor layer 133 is disposed on the first bonding electrode BE1 and the second bonding electrode BE2, and the first additional semiconductor layer 131 is disposed on the second additional semiconductor layer 133. The first additional semiconductor layer 131 may protrude to the outside of the second additional semiconductor layer 133 so that a portion of the lower surface of the first additional semiconductor layer 131 may be exposed from the second additional semiconductor layer 133. The first additional semiconductor layer 131 and the second additional semiconductor layer 133 may be layers that are formed in such a way that n-type and p-type impurities are doped on a specific material. For example, each of the first additional semiconductor layer 131 and the second additional semiconductor layer 133 may be layers where n-type and p-type impurities are doped on a material such as gallium nitride (GaN), indium aluminum phosphide (InAIP), gallium arsenide (GaAs) and the like. Additionally, the p-type impurities may be magnesium, zinc (Zn), beryllium (Be) and the like, and the n-type impurities may be silicon (Si), germanium, tin (Sn) and the like, but not limited thereto.

The additional light emitting layer 132 is disposed between the first additional semiconductor layer 131 and the second additional semiconductor layer 133. The additional light emitting layer 132 may receive holes and electrons from the first additional semiconductor layer 131 and the second additional semiconductor layer 133 to emit light. The additional light emitting layer 132 may be structured as a single layer or a multi-quantum well (MQW), and for example, made of indium gallium nitride (InGaN) or gallium nitride (GaN) and the like, but not limited thereto.

The first additional electrode 134 is disposed on the lower surface of the first additional semiconductor layer 131, exposed from the second additional semiconductor layer 133. The first additional electrode 134 may be disposed on the lower surface of the first additional semiconductor layer 131, exposed from the additional light emitting layer 132 and the second additional semiconductor layer 133. The first additional electrode 134 is an electrode for electrically connecting the driving transistor DT and the first additional semiconductor layer 131. The first additional electrode 134 may be made of a conductive material, e.g., a conductive transparent material such as indium tin oxide (ITO) or indium zinc oxide (IZO) and the like or a conductive opaque material such as titanium (Ti), gold (Au), silver (Ag), copper (Cu), or an alloy thereof, and the like, but not limited thereto.

The second additional electrode 135 is disposed on the lower surface of the second additional semiconductor layer 133. The second additional electrode 135 is an electrode for electrically connecting the power lines and the second additional semiconductor layer 133. The second additional electrode 135 may be made of a conductive material, e.g., a conductive transparent material such as indium tin oxide (ITO) or indium zinc oxide (IZO) and the like or a conductive opaque material such as titanium (Ti), gold (Au), silver (Ag), copper (Cu), or an alloy thereof, and the like, but not limited thereto.

Accordingly, while the light emitting element 120 is a lateral-structure LED chip where a pair of electrodes is disposed on the light emitting layer 122, the additional light emitting element 130 is a flip chip-structure LED chip where a pair of electrodes is disposed under the additional light emitting layer 132, and the light emitting element 120 and the additional light emitting element 130 may be comprised of different types of light emitting elements 120. Thus, the light emitting element 120 is a first type of LED chip (e.g., a lateral-structure LED chip) whereas the additional light emitting element is a second type of LED chip (e.g., a flip chip-structure LED chip) that is different from the first type of LED chip.

Then the encapsulation film 136 surrounding the first additional semiconductor layer 131, the additional light emitting layer 132, the second additional semiconductor layer 133, the first additional electrode 134 and the second additional electrode 135 is disposed. The encapsulation film 136 may be made of an insulation material and protect the first additional semiconductor layer 131, the additional light emitting layer 132 and the second additional semiconductor layer 133. Additionally, the additional encapsulation film 136 may have a contact hole that exposes the first additional electrode 134 and the second additional electrode 135 so that the first bonding electrode BE1 and the second bonding electrode BE2 may be electrically connected to the first additional electrode 134 and the second additional electrode 135, respectively.

Additionally, a portion of the lateral surface of the first additional semiconductor layer 131 may be exposed from the encapsulation film 136. As described above, a portion of the additional encapsulation film 136 may be torn off in the process of separating the light emitting element 120 manufactured on a wafer from the wafer. For example, a portion of the additional encapsulation film 136, adjacent to the edge at the upper side of the first additional semiconductor layer 131 of the additional light emitting element 130, may be torn off in the process where the light emitting element 120 separates from the wafer, and a portion at the upper side of the lateral surface of the first additional semiconductor layer 131 may be exposed to the outside. However, since the additional light emitting element 130 connects to the pixel circuit PX and the high potential power line VDD in such a way that the first additional electrode 134 and the second additional electrode 135 are bonded to the first bonding electrode BE1 and the second bonding electrode BE2 disposed under the additional light emitting element 130, a short-circuit failure caused by the first additional semiconductor layer 131 exposed from the additional encapsulation film 136 may be minimized.

Further, the first contact hole CH1 where the first bonding electrode BE1 is placed may be formed up to the third planarization layer 115c, the second planarization layer 115b and the adhesive layer AD. Accordingly, in the first contact hole CH1 of the repair sub pixel SP′, the first connection electrode CE1 may be electrically connected to the sensing layer TL, and the first bonding electrode BE1 may be electrically connected to the sensing layer TL through the first connection electrode CE1. Specifically, the light emitting element 120 may be transferred onto the adhesive layer AD, and before the second planarization layer 115b is formed, a plurality of contact holes including the first contact hole CH1 may be formed first on the adhesive layer AD. At this time, in a sub pixel SP to which the light emitting element 120 is transferred, the first contact hole CH1 may not be formed on the adhesive layer AD because of the light emitting element 120, and in a repair sub pixel SP′ to which the light emitting element 120 is not transferred, the adhesive layer AD at the position where the first contact hole CH1 is formed may be exposed to the outside, and accordingly, the first contact hole CH1 may be formed at the adhesive layer AD of the repair sub pixel SP′. The first contact hole CH1 of the adhesive layer AD formed in the repair sub pixel SP′ may connect to a first contact hole CH1 to be formed at the second planarization layer 115b and the third planarization layer 115c, later, to form one first contact hole CH1. Additionally, in the state where the first contact hole CH1 is formed at the adhesive layer AD, the second planarization layer 115b and the third planarization layer 115c may be formed, and a process of forming the first contact hole CH1 and the second contact hole CH2 may proceed. At this time, in a repair sub pixel SP′ to which the light emitting element 120 is not transferred, the light emitting element 120 is not disposed at a position where the first contact hole CH1 and the second contact hole CH2 are formed. Accordingly, the first contact hole CH1 and the second contact hole CH2 of the repair sub pixel SP′ may respectively have a greater depth than the first contact hole CH1 and the second contact hole CH2 of a normal sub pixel SP. In the normal sub pixel SP, the first contact hole CH1 and the second contact hole CH2 may be formed at a depth of up to the positions of the first electrode 124 and the second electrode 125 of the light emitting element 120, for example, may be formed up to the upper surface of each of the first electrode 124 and the second electrode 125 on the upper surface of the third planarization layer 115c. However, in the repair sub pixel SP′, the first contact hole CH1 may be formed up to the second planarization layer 115b and the adhesive layer AD from the third planarization layer 115c, so that the sensing layer TL is exposed at the first contact hole CH1, and the second contact hole CH2 may be formed up to the third planarization layer 115c and the second planarization layer 115b. As the depth of the second contact hole CH2 is less than the depth of the first contact hole CH1 since the second electrode 125 is disposed higher than the first electrode 124, the second contact hole CH2 may be formed to have a depth less than that of the first contact hole CH1 even in the repair sub pixel SP′.

Referring to FIG. 9, the first bonding electrode BE1 and the first connection electrode CE1 are electrodes for electrically connecting the additional light emitting element 130 and the driving transistor DT. However, in the first contact hole CH1 of the repair sub pixel SP′, the first bonding electrode BE1 and the first connection electrode CE1 are in the state of connecting to the sensing layer TL, and in the first area SA, an existing sensing layer TL may be in the state of connecting to the second reflective electrode RE2 that is the high potential power line VDD. Accordingly, in the case where the additional light emitting element 130 immediately connects to the first bonding electrode BE1 and the first connection electrode CE1, a failure where the first additional electrode 134 of the additional light emitting element 130 connects to the high potential power line VDD through the sensing layer TL, as well as the driving transistor DT, may occur. Thus, in the repair sub pixel SP′, the first area SA may be in a damaged state, to separate the first additional electrode 134 of the additional light emitting element 130 and the high potential power line VDD.

The first area SA is an area where the second reflective electrode RE2 and the sensing layer TL are electrically connected to each other. Additionally, in a repair sub pixel SP′ to which the light emitting element 120 is not transferred, a portion of the second reflective electrode RE2 and a portion of the sensing layer TL that are disposed in the first area SA may be in the state of being damaged, or the sensing layer TL may be in the state of being disconnected, and the sensing layer TL and the second reflective electrode RE2 may be in the state of being insulated. Thus, in the repair sub pixel SP′ where a defective sub pixel SP is repaired, the sensing layer TL and the second reflective electrode RE2 are insulated to connect the first additional electrode 134 of the additional light emitting element 130 only to the driving transistor DT, and to drive the additional light emitting element 130 normally.

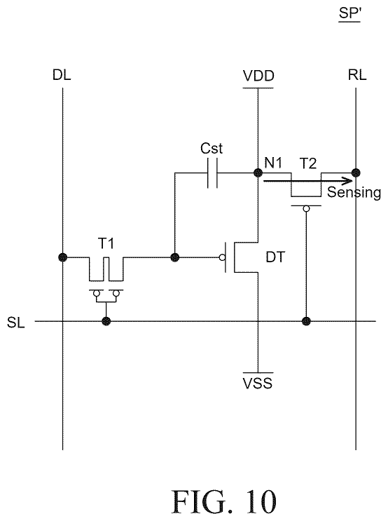

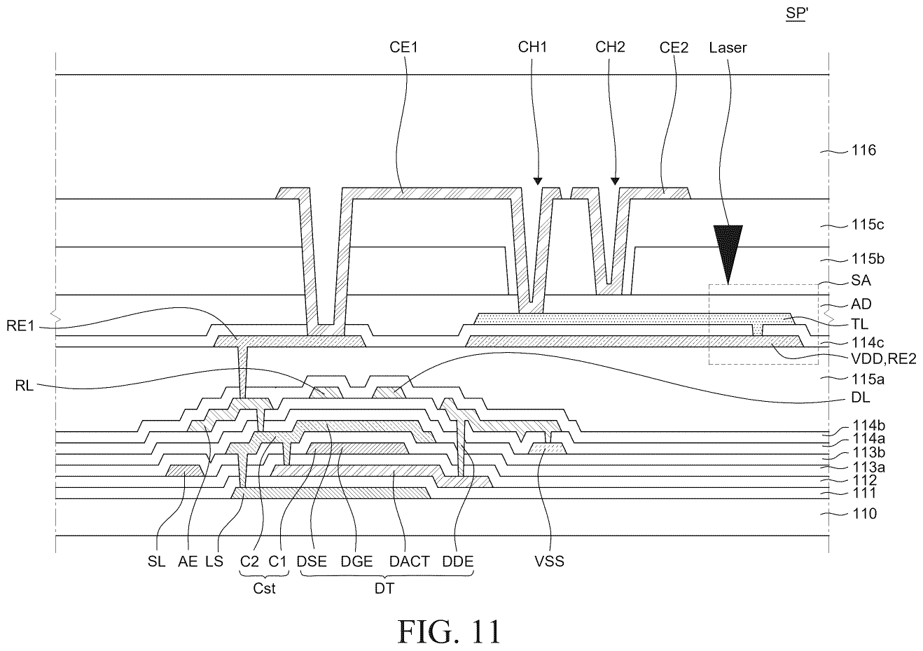

Hereinafter, a process in which a defective sub pixel SP is repaired to form a repair sub pixel SP′ in the display device 100 of one embodiment is described with reference to FIGS. 10 and 11.

FIG. 10 is a circuit diagram of a repair sub pixel of the display device according to one embodiment prior to a repair process. FIG. 11 is a cross-sectional view of a repair sub pixel of the display device according to one embodiment. FIG. 10 is a circuit diagram of a repair sub pixel SP′ before the additional light emitting element 130 is transferred according to one embodiment, and FIG. 11 is a cross-sectional view of a repair sub pixel SP′ before the additional light emitting element 130 is transferred according to one embodiment.

First, in the process of manufacturing the display device 100, an inspection for detecting a sub pixel SP where a non-transfer failure of the light emitting element 120 occurs may be performed. For example, the plurality of light emitting elements 120 are transferred, and in the state where the first connection electrode CE1 and the second connection electrode CE2 are formed, the plurality of light emitting elements 120 are driven to detect a sub pixel SP where a non-transfer failure occurs.

Referring to FIGS. 10 and 11, in a defective sub pixel SP to which the light emitting element 120 is not transferred, the first contact hole CH1 and the second contact hole CH2 may have a relatively great depth since the light emitting element 120 is not disposed in the first contact hole CH1 and the second contact hole CH2, as described above. Additionally, the sensing layer TL may be exposed at the first contact hole CH1 formed to have a greater depth than that of the second contact hole CH2. Accordingly, the short-circuit failure of the sensing layer TL and the first connection electrode CE1 may occur in the first contact hole CH1. Thus, in the first contact hole CH1 of the defective sub pixel SP, the driving source electrode DSE of the driving transistor DT and the high potential power line VDD may connect to each other through the first connection electrode CE1.

Further, a voltage of a first node N1, i.e., a voltage of the driving source electrode DSE of the driving transistor DT, may be sensed through a second transistor T2. The second transistor T2 may be turned on to deliver a voltage of the driving source electrode DSE to the reference line RL, and the data driver DD may sense a voltage of a first node N1 delivered to the reference line RL.

At this time, in a sub pixel SP where the light emitting element 120 is disposed, e.g., in a circuit structure as shown in FIG. 4, the light emitting element 120 is in the state of connecting to the first node N1, and in a sub pixel SP to which the light emitting element 120 is not transferred, e.g., in a circuit structure as shown in FIG. 10, the high potential power line VDD is in the state of directly connecting to the first node N1. Accordingly, the voltage of the first node N1 may vary depending on the presence and absence of the light emitting element 120, and based on results of sensing of the voltage of the first node N1, a non-transfer failure of the light emitting element 120 may be detected. Thus, the voltage of the first node N1 may be sensed to detect a non-transfer failure of the light emitting element 120 readily.

Then referring to FIG. 11, in a sub pixel SP where a non-transfer failure is detected, a laser is transferred to the first area SA to insulate the sensing layer TL from the high potential power line VDD. As described above, the first bonding electrode BE1 and the first connection electrode CE1 for connecting the driving transistor DT and the additional light emitting element 130 may connect to the sensing layer TL in the repair sub pixel SP′. At this time, as the additional light emitting element 130 is immediately transferred without disconnecting the sensing layer TL, the first additional electrode 134 of the additional light emitting element 130 may electrically connected to both of the driving transistor DT and the high potential power line VDD through the first bonding electrode BE1, the first connection electrode CE1 and the sensing layer TL, thereby preventing a failure.

Accordingly, after a process of inspecting a non-transfer failure is completed, a laser is irradiated to the first area SA of a defective sub pixel SP, to insulate the sensing layer TL and the high potential power line VDD. For example, a laser may be irradiated to the first area SA of a sub pixel SP where a non-transfer failure is sensed, to destroy the connect hole portion to which the high potential power line VDD and the sensing layer TL connect to each other. In another example, a laser may be irradiated to the first area SA, to disconnect a portion of the sensing layer TL placed in the first area SA, and the remaining portion of the sensing layer TL not placed in the first area SA may disconnect. Further, in the drawings, the disconnection of the sensing layer TL is only illustrated, but depending on the intensity of a laser, both of the sensing layer TL and the high potential power line VDD disposed in the first area SA may disconnect. Accordingly, in the first area SA, a process of insulating the sensing layer TL and the high potential power line VDD may proceed to connect the sensing layer TL, the first bonding electrode BE1 and the first connection electrode CE1 only to the driving transistor DT in the repair sub pixel SP′.

After the process of insulating the sensing layer TL and the high potential power line VDD is completed, the first bonding electrode BE1 and the second bonding electrode BE2 may be respectively formed in the first contact hole CH1 and the second contact hole CH2. Then the additional light emitting element 130 is transferred onto the first bonding electrode BE1 and the second bonding electrode BE2 to form a repair sub pixel SP′.

In the display device 100 of one embodiment, a non-transfer failure of the light emitting element 120 may be detected without a lighting test. The sensing layer TL may be disposed in an area to which the light emitting element 120 is to be transferred, and electrically connected to the high potential power line VDD. Then at a time when the first contact hole CH1 and the second contact hole CH2 are formed, the first contact hole CH1 and the second contact hole CH2 may be formed relatively deeply in a sub pixel SP to which the light emitting element 120 is not transferred, and the sensing layer TL may be exposed at the first contact hole CH1. Additionally, in the following process, as the first connection electrode CE1 connects to the sensing layer TL, a short-circuit failure where the sensing layer TL, the high potential power line VDD and the driving transistor DT electrically connected may occur. Then the voltage of the first node N1, i.e., the voltage of the driving source electrode DSE, may be sensed through the second transistor T2 so that a sub pixel SP to which the light emitting element 120 is not transferred is readily detected.

In the display device 100 of one embodiment, the additional light emitting element 130 may be transferred to a defective sub pixel SP to which the light emitting element 120 is not transferred, to form a repair sub pixel SP′ that is driven normally. After the defective sub pixel SP to which the light emitting element 120 is not transferred is first detected in the above-descried inspection process, the first bonding electrode BE1 and the second bonding electrode BE2 may be formed to bond the additional light emitting element 130 to the defective sub pixel SP. The first bonding electrode BE1 and the second bonding electrode BE2 may have a planar upper surface, so that the additional light emitting element 130 may be readily bonded onto the first bonding electrode BE1 and the second bonding electrode BE2. Additionally, the first bonding electrode BE1 and the second bonding electrode BE2 may be respectively configured to fill a space formed by the first contact hole CH1 and the second contact hole CH2, so that an air gap between the additional light emitting element 130, and the first connection electrode CE1 and the second connection electrode CE2 is removed. Thus, the additional light emitting element 130 may be disposed stably in the repair sub pixel SP′, and the removal of the air gap may help to prevent moisture and oxygen and the like in the air gap from damaging the components in the display device 100.

In the display device 100 of one embodiment, the sensing layer TL of the repair sub pixel SP′ may be insulated from the high potential power line VDD to drive the additional light emitting element 130 normally. The sensing layer TL may be disposed to overlap the first contact hole CH1, while being electrically connected to the high potential power line VDD, to detect a non-transfer failure of the light emitting element 120. Additionally, in a sub pixel SP to which the light emitting element 120 is not transferred, the sensing layer TL may be electrically connected to the first connection electrode CE1 and the driving transistor DT and the high potential power line VDD, and sense the voltage of the driving source electrode DSE to detect a non-transfer failure. The first additional electrode 134 of the additional light emitting element 130 needs to be electrically connected with the driving transistor DT through the first connection electrode CE1, but in the state where the sensing layer TL continuously electrically connected to the high potential power line VDD, a failure where the first additional electrode 134 connects both of the driving source electrode DSE and the high potential power line VDD may occur. Therefore, before the additional light emitting element 130 is transferred, a laser may be irradiated to the first area SA, to insulate the sensing layer TL and the high potential power line VDD. For example, the sensing layer TL and the high potential power line VDD disposed in the first area SA may disconnect from the sensing layer TL and the high potential power line VDD not disposed in the first area SA, or the contacts holes of the sensing layer TL and the high potential power line VDD may be destroyed. Thus, in the repair sub pixel SP′, the sensing layer TL may separate from the high potential power line VDD, and the first additional electrode 134 of the additional light emitting element 130 may be electrically connected only to the driving transistor DT and operate normally.

The exemplary embodiments of the present disclosure can also be described as follows:

According to an aspect of the present disclosure, a display device includes a substrate having a plurality of sub pixels and one or more repair sub pixels disposed thereon, a high potential power line disposed in the plurality of sub pixels and the repair sub pixels, a driving transistor disposed in each of the plurality of sub pixels and each of the repair sub pixels, a sensing layer disposed on the high potential power line in each of the plurality of sub pixels and each of the repair sub pixels, an insulation layer disposed on the sensing layer in the plurality of sub pixels and the repair sub pixels, a light emitting element disposed between the sensing layer and the insulation layer in each of the plurality of sub pixels, and an additional light emitting element disposed on the insulation layer in the repair sub pixels.

The display device may further include an adhesive layer disposed between the sensing layer and the light emitting element under the insulation layer, the sensing layer may be electrically connected to the high potential power line through a contact hole of the adhesive layer in each of the plurality of sub pixels, and the sensing layer may be insulated from the high potential power line in the repair sub pixels.

The display device may further include a first connection electrode disposed on the light emitting element in each of the plurality of sub pixels, disposed under the additional light emitting element in the repair sub pixels, and electrically connected to the driving transistor, and the first connection electrode may be disposed on the insulation layer.

In the repair sub pixels, the additional light emitting element may be disposed on the first connection electrode and the insulation layer.

The first connection electrode of the repair sub pixels may be electrically connected to the sensing layer through a first contact hole of the insulation layer, and the first connection electrode of the plurality of sub pixels may be electrically connected to the light emitting element through the first contact hole of the insulation layer.

In each of the plurality of sub pixels, the sensing layer may be spaced apart from the first connection electrode with the light emitting element interposed therebetween.

A depth of the first contact hole of the plurality of sub pixels may be less than a depth of the first contact hole of the repair sub pixels.

The display device may further include a second connection electrode disposed on the light emitting element in each of the plurality of sub pixels, disposed under the additional light emitting element in the repair sub pixels, and electrically connected to the high potential power line, and the second connection electrode of the plurality of sub pixels may be electrically connected to the light emitting element through a second contact hole of the insulation layer.

A depth of the second contact hole of the plurality of sub pixels may be less than a depth of the second contact hole of the repair sub pixel.

The second connection electrode of the repair sub pixels may electrically connect the additional light emitting element and the high potential power line.

The display device may further include a first bonding electrode disposed between the first connection electrode and the additional light emitting element in the repair sub pixels, and a second bonding electrode disposed between the second connection electrode and the additional light emitting element in the repair sub pixels, the first bonding electrode and the second bonding electrode may be respectively configured to fill the first contact hole and the second contact hole.

The light emitting element may be a light emitting diode (LED) having a lateral structure, and the additional light emitting element may be an LED having a flip chip structure.

The display device may further include a first planarization layer disposed on the driving transistor. The insulation layer may include a second planarization layer disposed on the sensing layer and having an opening that is configured to overlap the first contact hole and the second contact hole, and a third planarization layer disposed on the second planarization layer, in each of the plurality of sub pixels, the light emitting element may be disposed in the opening of the second planarization layer, and in the repair sub pixels, the third planarization layer may be disposed in the opening of the second planarization layer.

A depth of the first contact hole of the plurality of sub pixels may be greater than a depth of the second contact hole of the plurality of sub pixels, and a depth of the first contact hole of the repair sub pixel may be greater than a depth of the second contact hole of the repair sub pixel.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a plurality of sub pixels and a repair sub pixel on the substrate;
a high potential power line in the plurality of sub pixels and the repair sub pixel;
a plurality of driving transistors, each driving transistor in a corresponding one of the plurality of sub pixels or the repair sub pixel;
a plurality of light emitting elements on the high potential power line, each light emitting element in a corresponding one of the plurality of sub pixels;
an insulation layer on the plurality of light emitting elements such that plurality of light emitting elements are between at least a portion of the insulation layer and the high potential power line; and
an additional light emitting element in the repair sub pixel, the additional light emitting element on the insulation layer such that insulation layer is between the additional light emitting element and the high potential power line.

2. The display device of claim 1, further comprising:
a plurality of sensing layers, each sensing layer on the high potential power line in each of the plurality of sub pixels and the repair sub pixel.

3. The display device of claim 2, further comprising:
an adhesive layer between the plurality of sensing layers and the plurality of light emitting elements,
wherein each sensing layer in the plurality of sub pixels is electrically connected to the high potential power line through a contact hole in the adhesive layer, and the sensing layer in the repair sub pixel is insulated from the high potential power line.

4. The display device of claim 2, further comprising:
a first connection electrode in a sub pixel from the plurality of sub pixels is on the insulation layer such that a portion of the first connection electrode is above a light emitting element of the plurality of light emitting elements that is in the sub pixel, the first connection electrode of the sub pixel electrically connected to a driving transistor from the plurality of driving transistors that is in the sub pixel; and
a first connection electrode of the repair sub pixel is on the insulation layer such that a portion of the first connection electrode is between the additional light emitting element and the insulation layer, the first connection electrode of the repair sub pixel electrically connected to a driving transistor from the plurality of driving transistors that is in the repair sub pixel.

5. The display device of claim 4, wherein the additional light emitting element of the repair sub pixel is farther from the substrate than the first connection electrode of the repair sub pixel.

6. The display device of claim 5, wherein the first connection electrode of the repair sub pixel is electrically connected to the sensing layer of the repair sub pixel through a first contact hole in a portion of the insulation layer that is in the repair sub pixel, and the first connection electrode of the sub pixel is electrically connected to the light emitting element through a first contact hole in a portion of the insulation layer that is in the sub pixel.

7. The display device of claim 6, wherein the sensing layer of the sub pixel is spaced apart from the first connection electrode of the sub pixel with the light emitting element between the first connection electrode of the sub pixel and the sensing layer of the sub pixel.

8. The display device of claim 6, wherein a depth of the first contact hole of the sub pixel is less than a depth of the first contact hole of the repair sub pixel.

9. The display device of claim 6, further comprising:
a second connection electrode of the sub pixel that is above the light emitting element and is electrically connected to the light emitting element through a second contact hole in a portion of the insulation layer in the sub pixel and is electrically connected to the high potential power line; and
a second connection electrode of the repair sub pixel that is electrically connected to the additional light emitting element through a second contact hole in a portion of the insulation layer in the repair sub pixel,
wherein a portion of the second connection electrode of the repair sub pixel is between the additional light emitting element and the insulation layer.

10. The display device of claim 9, wherein a depth of the second contact hole of the sub pixel is less than a depth of the second contact hole of the repair sub pixel.

11. The display device of claim 9, wherein the second connection electrode of the repair sub pixel electrically connects the additional light emitting element to the high potential power line.

12. The display device of claim 9, further comprising:
a first bonding electrode connected to the additional light emitting element, the first bonding electrode between the first connection electrode of the repair sub pixel and the additional light emitting element; and
a second bonding electrode connected to the additional light emitting element, the second bonding electrode between the second connection electrode of the repair sub pixel and the additional light emitting element,
wherein the first bonding electrode fills the first contact hole of the repair sub pixel and the second bonding electrode fills the second contact hole of the repair sub pixel.

13. The display device of claim 1, wherein at least one of the plurality of light emitting elements is a light emitting diode having a lateral structure, and the additional light emitting element is a light emitting diode having a flip chip structure.

14. The display device of claim 9, further comprising:
a first planarization layer on the plurality of driving transistors,
wherein the insulation layer comprises:
a second planarization layer on the plurality of sensing layers, the second planarization layer having an opening that overlaps the first contact hole and the second contact hole of the sub pixel and the first contact hole and the second contact hole of the repair sub pixel; and
a third planarization layer on the second planarization layer,
wherein the light emitting element of the sub pixel is in the opening of the second planarization layer, and the third planarization layer is in the opening of the second planarization layer in the repair sub pixel.

15. The display device of claim 9, wherein a depth of the first contact hole of the sub pixel is greater than a depth of the second contact hole of the sub pixel, and a depth of the first contact hole of the repair sub pixel is greater than a depth of the second contact hole of the repair sub pixel.

16. A display device comprising:
a substrate;
a sub pixel and a repair sub pixel on the substrate;
a first driving transistor in the sub pixel and a second driving transistor in the repair sub pixel;
a high potential power line in the sub pixel and the repair sub pixel;
a first insulating layer on the high potential power line in the sub pixel and the repair sub pixel;
a second insulating layer on the first insulating layer in the sub pixel and the repair sub pixel;
a first light emitting element in the sub pixel, the first light emitting element electrically connected to the first driving transistor;
a second light emitting element in the repair sub pixel, the second light emitting element connected to the second driving transistor;
a first connection electrode in the sub pixel that is electrically connected to the first light emitting element and is disposed in a first contact hole that extends through the second insulating layer without extending through the first insulating layer in the sub pixel; and
a first connection electrode in the repair sub pixel that is electrically connected to the second light emitting element and is disposed in a first contact hole that extends through the second insulating layer and the first insulating layer in the repair sub pixel.

17. The display device of claim 16, wherein the first light emitting element and the second light emitting element emit a same color of light.

18. The display device of claim 17, wherein the sub pixel that includes the first light emitting element and the repair sub pixel that includes the second light emitting element are included in a same pixel.

19. The display device of claim 16, wherein the second light emitting element is farther from the substrate than the first light emitting element.

20. The display device of claim 16, further comprising:
a first sensing layer in the sub pixel, the first sensing layer between the first light emitting element and the high potential power line and electrically connected to the high potential power line;
a second sensing layer in the repair sub pixel, the second sensing layer between the high potential power line and the first insulating layer and insulated from the high potential power line.

21. The display device of claim 20, wherein the first connection electrode of the repair sub pixel is connected to the second sensing layer through the first contact hole that extends through the second insulating layer and the first insulating layer in the repair sub pixel.

22. The display device of claim 21, further comprising:
a second connection electrode in the sub pixel that is connected to the first light emitting element through a second contact hole in the second insulating layer without extending through the first insulating layer in the sub pixel and is connected to the high potential power line through a third contact hole in the first insulating layer and the second insulating layer; and
a second connection electrode in the repair sub pixel that is connected to the second light emitting element and is connected to the high potential power line through a third contact hole in the first insulating layer and the second insulating layer in the repair sub pixel,
wherein the second connection electrode in the repair sub pixel is disposed in a second contact hole that extends through the first insulating layer and the second insulating layer in the repair sub pixel.

23. The display device of claim 22, further comprising:
a first bonding electrode disposed in the first contact hole of the repair sub pixel, the first bonding electrode electrically connecting the second light emitting element to the first connection electrode in the repair sub pixel; and
a second bonding electrode disposed in the second contact hole of the repair sub pixel, the second bonding electrode electrically connecting the second light emitting element to the second connection electrode in the repair sub pixel.

24. The display device of claim 16, wherein the first light emitting element is a light emitting diode having a lateral structure and the second light emitting element is a light emitting diode having a flip chip structure.
